(19) United States
(12) Patent Application Publication
(10) Pub. No.: US 2014/0134491 A1
(43) Pub. Date: May 15, 2014

(54) LITHIUM CONTAINING COMPOSITE OXIDE POWDER AND MANUFACTURING PROCESS FOR THE SAME

(71) Applicants: Yuki Sugimoto, Kariya-shi (JP); Naoto Yasuda, Kariya-shi (JP); Fumiya Kanetake, Kariya-shi (JP); Hideaki Shinoda, Kariya-shi (JP); Manabu Miyoshi, Kariya-shi (JP); Kyoichi Kinoshita, Kariya-shi (JP); Toru Abe, Kariya-shi (JP)

(72) Inventors: Yuki Sugimoto, Kariya-shi (JP); Naoto Yasuda, Kariya-shi (JP); Fumiya Kanetake, Kariya-shi (JP); Hideaki Shinoda, Kariya-shi (JP); Manabu Miyoshi, Kariya-shi (JP); Kyoichi Kinoshita, Kariya-shi (JP); Toru Abe, Kariya-shi (JP)

(73) Assignee: KABUSHIKI KAISHA TOYOTA JIDOSHOKKI, Kariya-shi, Aichi (JP)

(21) Appl. No.: 14/128,744

(22) PCT Filed: Jun. 22, 2012
(86) PCT No.: PCT/JP2012/004070

§ 371 Date: Dec. 23, 2013

(30) Foreign Application Priority Data
Jun. 24, 2011 (JP) 2011-140820

(51) Int. Cl. H01M 4/505; C30B 9/06

(52) U.S. Cl. CPC H01M 4/505; C30B 9/06
USPC 429/221; 429/224; 429/223; 117/79; 117/3

(57) ABSTRACT

Provided is a lithium containing composite oxide powder suitable for the positive electrode active material of the non-aqueous electrolysis solution secondary battery such as the lithium ion secondary battery, and a manufacturing process for the same. A lithium containing composite oxide powder includes a single crystal particle containing a lithium containing composite oxide that is manufactured by a molten salt method and that includes at least lithium and another one or more metal elements and in which a crystal structure belongs to a lamellar rock salt structure, wherein an average primary particle diameter is greater than or equal to 200 nm and smaller than or equal to 30 μm. The lithium containing composite oxide powder is grown by reacting the metal containing ingredient in the molten salt of the lithium hydroxide at a reaction temperature of higher than or equal to 650° C. and lower than or equal to 900° C.

### TECHNICAL FIELD

The present invention relates to a lithium containing composite oxide powder mainly used for a positive electrode material of a lithium secondary battery, and a non-aqueous electrolysis solution secondary battery using the lithium containing composite oxide powder.

### BACKGROUND ART

With advancement in portable electronic devices such as a portable telephone, a laptop, and the like, and practical realization of the electric automobile, and the like, a small, lightweight, and high capacity non-aqueous electrolysis solution secondary battery is becoming necessary in recent years. For example, the lithium ion secondary battery has, at a positive electrode and a negative electrode, an active material that can insert and desorb lithium (Li). The lithium ion secondary battery operates when the lithium ions move in an electrolysis solution provided between the electrodes.

The materials of the positive electrode, the negative electrode, and the electrolyte that configure the lithium ion secondary battery influence the performance of the lithium ion secondary battery. Among them, the material of the active material that forms the active material is actively being researched and developed. For example, the lithium containing composite oxide containing lithium and other metal elements having a lamellar rock salt structure of α-NaFeO₂ type such as Li₂MnO₃, LiCoO₂, LiNiO₂, LiFeO₂, and the like is known for the positive electrode active material of the lithium ion secondary battery.

A manufacturing process for the lithium containing composite oxide includes a solid phase method. For example, in Example 1 of patent literature 1, Ni—Mn—Co composite oxide powder (mol ratio of Ni/Mn/Co is 1/1/1) and lithium hydroxide-monohydrate powder are mixed such that Li/(Ni+Mn+Co) is 1.02 in mol ratio, and the mixture is held for 15 hours at 1000° C. to synthesize LiCo_{1/3}Ni_{1/3}Mn_{1/3}O₂. The obtained lithium containing composite oxide is a secondary particle in which a plurality of primary particles, each having an average particle diameter of 1.1 μm, is agglomerated. Thus, the lithium containing composite oxide synthesized by the solid phase method includes the secondary particle in which a plurality of fine particles is agglomerated, that is, a polycrystalline particle configured by a plurality of crystalline grains.

In patent literature 2, a single crystal is obtained through the solid phase method similar to the above. In Example 3 of patent literature 2, lithium nitrate and basic nickel carbonate are mixed such that the mol ratio of Ni and Li is 1:1.1, and the mixture is calcined for a long time at a high temperature to synthesize LiNiO₂ powder. However, as described above, the lithium containing composite oxide synthesized by the solid phase method is a polycrystal configured by a plurality of crystalline grains. In the example of patent literature 2, the grain growth of the crystalline grain advances by being calcined for a long time at a high temperature, so that the obtained calcined article is assumed to include secondary particles in which the large size crystalline grains are agglomerated. In the examples of patent literature 2, the LiNiO₂ powder including single crystals having an average particle diameter of smaller than or equal to 10 μm is obtained by grinding and classifying the calcined article.

In Example 4 of patent literature 3, MnCl₂ and LiNO₃ are mixed at a predetermined mol ratio (LiNO₃/MnCl₂=3.5), and the mixture further added with LiCl is heated for 8 hours at 800° C. to generate a mixed phase of LiMn₂O₄ and Li₂MnO₃. The Li₂MnO₃ obtained in such manner is described as being a plate-like single crystal of about 0.3 mm. The synthesizing method described in patent literature 3 is a so-called molten salt method, and is a method normally used to synthesize a fine lithium containing composite oxide.

### RELATED TECHNICAL LITERATURE

### Patent Literature

Patent literature No. 1: Japanese Unexamined Patent Pubrication (KOKAI) Gazette No. 2003-68299;

Patent literature No. 2: Japanese Unexamined Patent Pubrication (KOKAI) Gazette No. 7-114942;

Patent literature No. 3: Japanese Unexamined Patent Pubrication (KOKAI) Gazette No. 2001-316200;

### SUMMARY OF THE INVENTION

### Assignment to be Solved by the Invention

The lithium containing composite oxide synthesized by the solid phase method is a powder including polycrystalline particles, as described above. The polycrystalline particle includes a great number of crystal grain boundaries. Generally, the crystal grain boundary is one type of defect, and thus becomes the cause of particle disruption. An impurity having a different composition from the target lithium containing composite oxide exists at the crystal grain boundary. In the lithium ion secondary battery using the powder of the lithium containing composite oxide synthesized by the solid phase method as the positive electrode active material, the particles of the lithium containing composite oxide are easily disrupted from the crystal grain boundary with the repeated charging/discharging, and the impurity existing at the crystal grain boundary becomes the active site of the electrolysis solution decomposition when operating the lithium ion secondary battery at high voltage. Such phenomenon leads to lowering in cyclability, in particular, among the characteristics of the secondary battery.

In patent literature 2, the polycrystalline particle of LiNiO₂ synthesized by the solid phase method is ground to obtain the LiNiO₂ powder. That is, the disruption of the particles involved in the charging/discharging is suppressed by using the powder disrupted in advance. Since the crystalline grain configuring the polycrystalline particle includes single crystals, the LiNiO₂ powder after the grinding may contain single particles of single crystals formed by being ground at the crystal grain boundary. However, the LiNiO₂ powder after the grinding may be mixed with the impurity existing in the polycrystalline particle or may contain the single particle of the polycrystal depending on the extent of grinding.

Li₂MnO₃ disclosed in patent literature 3 is the single crystal grown by the molten salt method. In patent literature 3, it is an object to grow a large single crystal of about 0.3 mm, for example, that can be used in a micro-battery or a microscopic electrode. That is, the size of the single crystal grown in patent literature 3 is greater the more the order is different compared to the particle size desired for the positive electrode active material of the lithium ion secondary battery, and the like.

The inventors of the present invention have synthesized Li₂MnO₃ powder of fine particle form by the molten salt method in an aim of using the entire particle for the active material and not only the surface for the active material with respect to lithium manganese oxide. However, when the particle diameter of the Li₂MnO₃ powder is too small, the Li₂MnO₃ powder agglomerates and cannot be evenly dispersed in the active material layer when producing the electrode, and it is difficult to fill the fine particles at high density in the active material layer. Furthermore, the very small particles cannot be said as having satisfactory crystallinity even for the single crystal.

It is an object of the present invention to provide a lithium containing composite oxide powder suitable for the positive electrode active material of the non-aqueous electrolysis solution secondary battery such as the lithium ion secondary battery, and a manufacturing process for the same.

### Means for Solving the Assignment

A lithium containing composite oxide powder according to the present invention includes a single crystal particle containing a lithium containing composite oxide that is manufactured by a molten salt method and that includes at least lithium and another one or more metal elements and in which a crystal structure belongs to a lamellar rock salt structure, wherein an average primary particle diameter is greater than or equal to 200 nm and smaller than or equal to 30 μm.

The molten salt method is, in a broad sense, a method of growing crystals by using a high temperature solution containing molten salt of inorganic salt as a medium. In particular, the molten salt method in the present invention is a method for synthesizing a target chemical compound in the high temperature solution containing at least lithium and another metal element. In the present invention, in particular, the single crystal particle is preferably a particle consisting of single crystals synthesized in the molten salt of lithium hydroxide.

The lithium containing composite oxide powder according to the present invention consists of single crystal particles and thus does not have crystal grain boundaries, whereby disruption of the active material particles and decomposition of the electrolysis solution involved in charging/discharging are suppressed when the lithium containing composite oxide powder is used for the positive electrode active material of the non-aqueous electrolysis solution secondary battery. The lithium containing composite oxide powder according to the present invention contains particles of relatively large size, and thus can be filled in the active material layer evenly and at high density. Asa result, the non-aqueous electrolysis solution secondary battery excelling in cyclability and showing high capacity is obtained.

The present invention also relates to a manufacturing process for the lithium containing composite oxide powder according to the present invention described above, the method including single crystal growing step of reacting a metal containing ingredient, which includes a metal element, in a molten salt of a lithium hydroxide containing lithium of a mol ratio exceeding a theoretical composition of lithium contained in the lithium containing composite oxide at a reaction temperature of higher than or equal to 650° C. and lower than or equal to 900° C.; cooling step of cooling the molten salt of after the single crystal growing step; and collecting step of collecting the generated lithium containing composite oxide from a cooled solid body.

Normally, in the molten salt method, alkali fusion occurs in the molten salt, each ingredient is uniformly mixed, and the lithium containing composite oxide of fine particle form is synthesized. However, the inventors of the present invention, and the like found that the single crystal particle that is relatively large and that has satisfactory crystallinity can be grown by reacting the metal containing ingredient in the molten salt of lithium hydroxide at the reaction temperature of between 650° C. and 900° C.

According to the manufacturing process for the present invention, powder containing lithium containing composite oxide consisting of two or more types of metal elements, in which Li is essential, and having a crystal structure belonging to a lamellar rock salt structure is obtained. For example, lithium manganese oxide in which lithium and manganese are essential may be used for the lithium containing composite oxide. When the lithium manganese oxide has a lamellar rock salt structure, the average oxidation number of Mn is basically quadrivalent, but the average oxidation number of Mn of the lithium manganese oxide is tolerated to 3.8 valents to quadrivalent since the composition of the lithium containing composite oxide according to the present invention may be slightly deviated from the basic composition. The lithium containing composite oxide may be lithium nickel oxide, in which a crystal structure belongs to the lamellar rock salt structure, where the average oxidation number of Ni is basically trivalent when the lithium nickel oxide has a lamellar rock salt structure, but the average oxidation number of Ni of the lithium nickel oxide may be tolerated to 2.8 valents to trivalent. Similarly, the lithium containing composite oxide may be lithium cobalt oxide, in which a crystal structure belongs to the lamellar rock salt structure, or lithium iron oxide, in which a crystal structure belongs to the lamellar rock salt structure. When the lithium cobalt oxide and the lithium iron oxide have a lamellar rock salt structure, the average oxidation number of Co and Fe is basically a triad, but the average oxidation number of Co of the lithium cobalt oxide and Fe of the lithium iron oxide can be tolerated to 2.8 valents to triad. Specifically, the lithium containing composite oxide may be Li₂MnO₃, LiCoO₂, LiNiO₂, LiFeO₂, LiCo_{1/3}Ni_{1/3}Mn_{1/3}O₂, LiNi_{0.5}Mn_{0.5}O₂, and the like. The composition formula of the lithium containing composite oxide can be expressed as xLi₂M¹O₃.(1−x)LiM²O₂ (where 0≦x≦1, M₁ is one or more types of metal element in which quadrivalent Mn is essential, M² is one or more types of metal element in which at least one type of triad Co, triad Ni, and triad Fe is essential or two or more types of metal element in which a quadrivalent Mn is essential).

The lithium containing composite oxide powder obtained by the manufacturing process according to the present invention can be used for the positive electrode active material of the secondary battery such as lithium ion secondary battery, and the like. In other words, the present invention can be assumed as the positive electrode active material for the non-aqueous electrolysis solution secondary battery containing the lithium containing composite oxide powder according to the present invention.

### Effects of the Invention

When the lithium containing composite oxide powder according to the present invention is used for the positive electrode active material of the non-aqueous electrolysis solution secondary battery such as the lithium ion secondary battery, battery characteristics such as the cyclability of the non-aqueous electrolysis solution secondary battery enhance.

### BRIEF DESCRIPTION OF THE DRAWINGS

FIG. 1 is a figure substitution photograph showing the result of observing Li₂MnO₃ powder, which is a lithium containing composite oxide powder according to the present invention, with a scanning electron microscope (SEM).

FIG. 2 is a figure substitution photograph showing the result of observing Li₂MnO₃ powder, which is the lithium containing composite oxide powder according to the present invention, with the SEM.

FIG. 3 is a figure substitution photograph showing the result of observing LiCoO₂ powder, which is the lithium containing composite oxide powder according to the present invention, with the SEM.

FIG. 4 is a figure substitution photograph showing the result of observing LiNiO₂ powder, which is the lithium containing composite oxide powder according to the present invention, with the SEM.

FIG. 5 is a figure substitution photograph showing the result of observing LiCo_{1/3}Ni_{1/3}Mn_{1/3}O₂ powder, which is the lithium containing composite oxide powder according to the present invention, with the SEM.

FIG. 6 is a figure substitution photograph showing the result of observing LiCo_{1/3}Ni_{1/3}Mn_{1/3}O₂ fine powder with the SEM.

FIG. 7 is a graph showing charging/discharging characteristics of a secondary battery in which LiCoO₂ powder, which is the lithium containing composite oxide powder according to the present invention, is used for a positive electrode active material.

FIG. 8 is a graph showing charging/discharging characteristics of the secondary battery in which LiCo_{1/3}Ni_{1/3}Mn_{1/3}O₂ powder, which is the lithium containing composite oxide powder according to the present invention, is used for the positive electrode active material.

FIG. 9 is a differential scanning calorimetric curve of the lithium containing composite oxide powder according to the present invention in a charged state and a lithium containing composite oxide powder of the conventional art in a charged state.

### MODE FOR CARRYING OUT THE INVENTION

A mode for implementing a lithium containing composite oxide powder and a manufacturing process for the same according to the present invention will be hereinafter described. Unless particularly stated, numerical ranges “a to b” described in the present specification include a lower limit a and an upper limit b in the relevant range. The numerical range is configured by arbitrarily combining values including the upper limit value, the lower limit value, as well as the numerical values given in the example.

### <Lithium Containing Composite Oxide Powder>

The lithium containing composite oxide powder according to the present invention includes a single crystal particle containing the lithium containing composite oxide that includes at least Li and another one or more metal elements and in which a crystal structure belongs to a lamellar rock salt structure.

Expressing the lithium containing composite oxide having the crystal structure belonging to the lamellar rock salt structure with a composition formula, the composition formula of the lithium containing composite oxide having the crystal structure belonging to the lamellar rock salt structure is xLi₂M¹O₃.(1−x)LiM²O₂ (where 0≦x≦1, M¹ is one or more types of metal element in which a quadrivalent Mn is essential, M² is one or more types of metal element in which at least one type of triad Co, triad Ni, and triad Fe is essential or two or more types of metal elements in which a quadrivalent Mn is essential). A part of Li may be substituted with H, and Li of smaller than or equal to 60% and furthermore, smaller than or equal to 45% in atom ratio may be substituted with H. Most of the M¹ is preferably a quadrivalent Mn, but M¹ may have less than 50% and furthermore, less than 80% substituted with another metal element. Most of the M² is preferably triad Co, triad Ni, or triad Fe, but M² may have less than 50% and furthermore, less than 80% substituted with another metal element. The substitution element is preferably at least one type of metal element selected from Ni, Al, Co, Fe, Mg, Ti from the standpoint of the chargeable/dischargeable capacity of when used for the electrode material. The lithium containing composite oxide has the above described composition formula as the basic composition, and regardless to say, includes the lithium containing composite oxide slightly deviated from the above composition formula due to deficiency of Li, M¹, M² or O that inevitably occurs.

The lithium containing composite oxide is also expressed with composition formula: Li_{1.33-y}M¹_{0.67-z}M²_{y+z}O₂ (where M¹ is one or more types of metal element in which quadrivalent Mn is essential, M² is one or more types of metal element in which at least one type of triad Co, triad Ni, and triad Fe is essential or two or more types of metal element in which a quadrivalent Mn is essential, 0≦y≦0.33, 0≦z≦0.67). The same composition is expressed with either notation system.

Furthermore, specifically, the lithium containing composite oxide includes LiCoO₂, LiNiO₂, LiFeO₂, Li₂MnO₃, LiCo_{1/3}Ni_{1/3}Mn_{1/3}O₂, LiNi_{0.5}Mn_{0.5}O₂, or a solid solution including two or more types thereof. As described above, the composition formula of the lithium containing composite oxide may have the illustrated composition formula as the basic composition, and a part of Mn, Fe, Co, and Ni may be substituted with another metal element. A part of Li may be substituted with H. The composition formula of the lithium containing composite oxide may be slightly deviated from the composition formula due to deficiency of metal element or oxygen that inevitably occurs.

In particular, the lithium containing composite oxide having LiCo_{1/3}Ni_{1/3}Mn_{1/3}O₂, Li₂MnO₃, LiNiO₂, and the like as the basic component is sometimes used at a high cutoff voltage (e.g., greater than or equal to 4.4 V at Li reference) when used for the positive electrode active material of the non-aqueous electrolysis solution secondary battery. The decomposition of the electrolysis solution tends to easily occur at high voltage. Thus, the effect of suppressing the decomposition of the electrolysis solution becomes more significant in the non-aqueous electrolysis solution secondary battery using the lithium containing composite oxide powder according to the present invention having the above compositions.

The identification of the structure and the composition of the lithium containing composite oxide can be carried out by X ray diffraction (XRD), electron beam diffraction, emission spectrochemical analysis (ICP), and the like. In a high resolution image using a high resolution transmission electron microscope (TEM), the lamellar structure can be observed by finely processing a sample, even if the sample is a relatively large particle.

The lithium containing composite oxide powder according to the present invention has an average primary particle diameter of greater than or equal to 200 nm and smaller than or equal to 30 μm. The average primary particle diameter is obtained by measuring the maximum diameter (maximum value of the interval of the parallel lines when the particle is sandwiched by two parallel lines) of a plurality of particles from the microscope photograph of the SEM, and the like, and taking the average value of the maximum diameters. The powder having an average primary particle diameter of greater than or equal to 200 nm is easy to handle industrially. Specifically, the powder having an average primary particle diameter of greater than or equal to 200 nm is suppressed from the particles agglomerating at the time of producing the electrode, and hence can be evenly dispersed in the active material layer. Since the powder having an average primary particle diameter of greater than or equal to 200 nm has high crystallinity, it excels in characteristics such as filling property, thermal stability, and the like in the active material layer. The average primary particle diameter is preferably greater than or equal to 300 nm, greater than or equal to 500 nm, and more preferably, greater than or equal to 1 μm. On the other hand, When the average primary particle diameter is too large, the surface that makes contact with the electrolysis solution and contributes to the battery reaction reduces. However, sufficient battery characteristics can be obtained in terms of capacity, rate characteristics, and the like by realizing the average primary particle diameter of smaller than or equal to 30 μm. It is not realistic that the average primary particle diameter exceeds 30 μm even in view of the thickness of the positive electrode active material layer (normally about 30 μm to 100 μm) formed in the current collector. The average primary particle diameter is preferably smaller than or equal to 25 μm, smaller than or equal to 20 μm, and more preferably, smaller than or equal to 13 μm.

In the lithium containing composite oxide powder according to the present invention, the single crystal particle preferably consists of a single particle. In other words, the lithium containing composite oxide powder according to the present invention preferably includes the single particle of the single crystal manufactured through the molten salt method. The “single particle” in the present specification refers to the particle consisting of a single particle that does not have a crystal grain boundary, as opposed to the secondary particle obtained by agglomerating a plurality of polycrystalline particles including a plurality of crystalline grains or fine particles. It is known by the analysis of the electron beam diffraction image by the transmission electron microscope that the single particle is a single crystal.

When the lithium containing composite oxide powder according to the present invention is defined by the specific surface area, the specific surface area is preferably greater than or equal to 0.5 m²/g and smaller than or equal to 20 m²/g. The lithium containing composite oxide powder according to the present invention consists of a single crystal particle or preferably a single particle of the single crystal grown in the molten salt by the molten slat method, as opposed to the polycrystal (secondary particle) consisting of a plurality of fine crystalline grains or a powder (e.g., described in patent literature 2) including the single particle close to the single crystal obtained by grinding the polycrystal. Thus, the specific surface area of the lithium containing composite oxide powder according to the present invention is relatively small. When the specific surface area is in the above range, an appropriate contacting area with the electrolysis solution is ensured. The preferred specific surface area is 0.5 m²/g to 15 m²/g, 1 m²/g to 10 m²/g, and furthermore, 1.5 m²/g to 7 m²/g. In the present specification, the specific surface area adopts a value in which the lithium containing composite oxide powder is measured with the BET method.

### <Manufacturing Process for Lithium Containing Composite Oxide Powder>

Each step in the manufacturing process for the lithium containing composite oxide powder according to the present invention will now be described. The manufacturing process for the lithium containing composite oxide powder mainly includes single crystal growing step, cooling step, and collecting step, and also includes ingredient preparing step, precursor synthesizing step and/or calcining step, and the like as necessary.

First, the ingredient preparing step of preparing the metal containing ingredient and the molten salt ingredient may be carried out. In the ingredient preparing step, the metal containing ingredient and the molten salt ingredient are mixed. In this case, the metal containing ingredient of powder form obtained by grinding a single substance metal, metal compound, and the like, and the molten salt ingredient containing the powder of lithium hydroxide are mixed to obtain the ingredient mixture.

The metal containing ingredient is the ingredient that supplies one or more types of metal elements excluding Li. The valency of the metal element contained in the metal containing ingredient is not particularly limited. The valency of the metal element contained in the metal containing ingredient is preferably smaller than or equal to the valency of the metal element contained in the target lithium containing composite oxide. This is because in the manufacturing process for the lithium containing composite oxide powder according to the present invention, the single crystal is grown in the molten salt of the lithium hydroxide in a high state of oxidation, and hence becomes the quadrivalent Mn during the reaction even if divalent or triad Mn in the state of the ingredient, for example. Therefore, the metal containing ingredient such as the general single substance metal, metal compound, and the like used in the molten salt method can be used. Specifically, the Mn supply source includes manganese dioxide (MnO₂), dimanganese trioxide (Mn₂O₃), manganese monoxide (MnO), manganese tetratrioxide (Mn₃O₄), manganese hydroxide (Mn(OH)₂), manganese oxyhydroxide (MnOOH) and the like. The Co supply source includes cobalt oxide (CoO, Co₃O₄), cobalt nitrate (Co(NO₃)₂.6H₂O), cobalt hydroxide (Co(OH)₂), cobalt chloride (CoCl₂.6H₂O), cobalt sulfate (Co(SO₄).7H₂O) and the like. The Ni supply source includes nickel oxide (NiO), nickel nitrate (Ni(NO₃)₂.6H₂O), nickel sulfate (NiSO₄.6H₂O), nickel chloride (NiCl₂.6H₂O) and the like. The Fe supply source includes iron hydroxide (Fe(OH)₃), iron chloride (FeCl₃.6H₂O), iron oxide (Fe₂O₃), iron nitrate (Fe(NO₃)₃.9H₂O), iron sulfate (FeSO₄.9H₂O) and the like. The supply source of other metal elements includes aluminum hydroxide (Al(OH)₃), aluminum nitrate (Al(NO₃)₃.9H₂O), copper oxide (CuO), copper nitrate (Cu(NO₃)₂.3H₂O), calcium hydroxide (Ca(OH)₂) and the like. The metal compound in which a part of the metal element contained in such oxides, hydroxides, or metal salt is substituted with another metal element (e.g., Cr, Mn, Fe, Co, Ni, Al, Mg etc.) may be adopted.

Among the metal compounds described above, MnO₂ is preferable for the Mn supply source, Co(OH)₂ is preferable for the Co supply source, Ni(OH)₂ is preferable for the Ni supply source, and Fe(OH)₃ is preferable for the Fe supply source, which are easily available and which of relatively high purity can be obtained.

Through the use of two or more types selected from the single substance metal and the metal compound, the lithium containing composite oxide powder containing two or more types of metal elements and the lithium containing composite oxide powder in which the metal element other than Li is substituted with another metal element can be manufactured, for example.

When the metal containing ingredient contains two or more types of metal elements, the compound containing the same may be synthesized in advance as a precursor. In other words, the precursor synthesizing step of obtaining a precipitation with the aqueous solution containing at least two types of metal elements having alkali property may be carried out before preparing the ingredient. The aqueous solution is obtained by dissolving in water an aqueous inorganic salt, specifically, nitrate, sulfate, chloride salt, and the like and making the aqueous solution alkaline with alkali metal hydroxide, ammonia water, and the like, where the precursor is generated as the precipitation. In particular, when the lithium containing composite oxide to synthesize is the lithium nickel composite oxide containing Ni, a manufacturing process using the precursor is preferably adopted since the generation of a by-product (NiO), which is difficult to remove, can be suppressed through the use of the manufacturing process using the precursor.

In the manufacturing process according to the present invention, the molten salt ingredient mainly may contain lithium hydroxide since the single crystal is grown in the molten salt of the lithium hydroxide. The lithium hydroxide may use anhydride (LiOH) or may use hydrate (LiOH.H₂O), but the lithium hydroxide provided for the single crystal growing step, to be described later, is preferably in the dewatered state. The molten salt ingredient desirably does not contain compounds other than the lithium hydroxide and substantially contains only the lithium hydroxide. However, the lithium hydroxide sometimes contains a small amount of lithium carbonate as an impurity since it has a property of absorbing carbon dioxide in the atmosphere to become the lithium carbonate. In particular, when obtaining the lithium containing composite oxide having the lamellar rock salt structure as in the present invention, the lithium hydroxide is desirably used alone as the molten salt ingredient from the standpoint of oxidation power, and oxides such as lithium peroxide, hydroxides such as potassium hydroxide, sodium hydroxide, and the like, and metal salts such as lithium nitrate, and the like are preferably not contained as they have the possibility of affecting the oxidation power of the lithium hydroxide.

The compound ratio of the metal containing ingredient and the molten salt ingredient is appropriately selected according to the proportion of the Li and the metal element contained in the lithium containing composite oxide to be manufactured. The molten salt ingredient is not only the supply source of lithium, and also plays a role of maintaining the oxidation state of the molten salt. Thus, the molten salt ingredient contains lithium exceeding the theoretical composition of the lithium to be contained in the lithium containing composite oxide to be manufactured. The theoretical composition of the lithium contained in the target lithium containing composite oxide with respect to the lithium contained in the molten salt ingredient (Li of lithium containing composite oxide/Li of molten salt ingredient) is less than one in mol ratio. From the standpoint of obtaining the powder having a large average primary particle diameter, Li of the lithium containing composite oxide/Li of the molten salt ingredient is preferably between 0.01 and 0.4 in mol ratio, in which case, the single crystal particle is easily obtained with single particle. The mol ratio is more preferably between 0.02 and 0.3, and between 0.04 and 0.2. when the Li of lithium containing composite oxide/Li of molten salt ingredient is smaller than 0.01 in mol ratio, this is not desirable in terms of manufacturing efficiency since the amount of lithium containing composite oxide to generate reduces with respect to the amount of molten salt ingredient to use. when the Li of lithium containing composite oxide/Li of molten salt ingredient is smaller than or equal to 0.4 in mol ratio, the molten salt for dispersing the metal containing ingredient sufficiently exists, the agglomeration of the lithium containing composite oxide in the molten salt is suppressed, and furthermore, the polycrystalline particle is less likely to be generated.

Prior to the single crystal growing step, the drying step of drying the molten salt ingredient may be at least carried out. The drying step mainly aims to dewater lithium hydroxide monohydrate, but the drying step is effective even when using the anhydrous lithium hydroxide in the case that a compound having high hydroscopic property is used for the metal containing ingredient. The water existing in the molten salt consisting of the molten salt ingredient including the lithium hydroxide in the single crystal growing step has very high pH. When the single crystal growing step is carried out under the existence of water of high pH, the water contacts the crucible and the component of the crucible may possibly elute to the molten salt, although the amount is very small, depending on the type of crucible. In the drying step, the moisture of the ingredient mixture is removed, which leads to suppressing the elution of the component of the crucible in the single crystal growing step. Furthermore, the water can be prevented from boiling and the molten salt from scattering in the single crystal growing step by removing the moisture from the ingredient mixture in the drying step. In the drying step, vacuum drying is carried out for 2 to 24 hours at between 80° C. and 150° C. when vacuum dryer is used.

The single crystal growing step is a step of carrying out the reaction in the molten salt consisting of molten salt ingredient. The single crystal growing step is carried out at a reaction temperature of between 650° C. and 900° C., which reaction temperature corresponds to the temperature of the molten salt. With the reaction temperature of between 650° C. and 900° C., single crystal consisting of lithium containing composite oxide belonging to the lamellar rock salt structure and having high crystallinity is grown. With the reaction temperature of lower than 650° C., the particles of small particle diameter tend to easily form, which is not desirable. The more desirable reaction temperature is higher than or equal to 675° C., and furthermore, higher than or equal to 700° C. The upper limit of the reaction temperature is lower than the decomposition temperature of the lithium hydroxide, and is desirably lower than or equal to 900° C. and more desirably lower than or equal to 875° C. When the reaction temperature is between 700° C. and 900° C., the single crystal can be grown under stable conditions, and hence such temperature is particularly desirable. The generation of impurities can be suppressed by causing the reaction in the molten salt in a relatively low temperature range of lower than or equal to 850° C. and lower than or equal to 825° C. The existence of impurities is assumed to lower the thermal stability of the lithium containing composite oxide powder. The thermal stability of the lithium containing composite oxide powder will be described in detail later.

The atmosphere for carrying out the single crystal growing step is not particularly limited, and is to be carried out in air medium. The lithium containing composite oxide having the lamellar rock salt structure can be easily obtained in a single phase by carrying out the single crystal growing step in the oxygen containing atmosphere such as the air medium. However, when the oxygen concentration of the reaction atmosphere becomes high, the particle diameter of the lithium containing composite oxide to be synthesized tends to become small, and hence the oxygen gas concentration in the atmosphere is to be smaller than or equal to 50% by volume and furthermore, between 15% by volume and 25% by volume from the standpoint of greatly growing the single crystal particle.

The cooling step is a step of cooling the molten salt after the single crystal growing step. In the cooling step, the molten salt is desirably cooled at a slow speed until reaching the melting point of the molten salt or the room temperature from the reaction temperature from the standpoint of greatly growing the single crystal particle. Specifically, the cooling speed of lower than or equal to 100° C./hr and furthermore, lower than or equal to 60° C./hr is desired. Therefore, in the cooling step, the cooling speed is desirably adjusted to realize gradual cooling with the high temperature molten salt after the termination of the reaction contained in a heating furnace. The lower limit of the cooling speed is not particularly limited, but for example, a very slow cooling speed of lower than 15° C./hr is not desirable since the production efficiency is not satisfactory. Since the molten salt solidifies due to cooling, the mixture of the synthesized lithium containing composite oxide and the molten salt is obtained as a solid body after the cooling step.

The collecting step is a step of collecting the generated lithium containing composite oxide from the cooled solid body. Specifically, a separation and collecting step of dissolving the molten salt solidified by the cooling step in polar protic solvent, and separating the lithium containing composite oxide generated in the single crystal growing step from the solidified molten salt is preferred. The polar protic solvent is adopted in the present step as it can dissolve the solidified molten salt (i.e., lithium hydroxide). A specific example of the polar protic solvent includes pure water such as ion exchange water, alcohol such as ethanol, and the like, one type of which can be used alone or two or more types can be combined and used. The solidified molten salt easily dissolves in the polar protic solvent, and the lithium containing composite oxide that is less likely to dissolve in the polar protic solvent remains without dissolving in the solvent. Thus, the molten salt and the lithium containing composite oxide are easily separated. The collecting method of the lithium containing composite oxide is not particularly limited, but the lithium containing composite oxide can be collected by centrifugal separating or filtering the solution. The collected lithium containing composite oxide may be dried. In the collecting step, the lithium containing composite oxide of powder form can be obtained by lightly grinding, and the like, as necessary.

After the collecting step, a proton substituting step of substituting a part of the Li of the lithium containing composite oxide powder with hydrogen (H) may be carried out. In the proton substituting step, the lithium containing composite oxide powder after the collecting step is brought into contact with the solvent such as diluted acid, and the like to easily substitute a part of the Li with H.

The calcining step of calcining the lithium containing composite oxide powder collected in the collecting step may be carried out.

In the calcining step, heat is applied on the lithium containing composite oxide powder, so that the residual stress existing in the crystal of the lithium containing composite oxide is removed and the lithium containing composite oxide powder in which the impurities such as lithium hydroxide, which are not completely removed in the separation and collecting step, are reduced is obtained. Furthermore, when the lithium containing composite oxide has Li deficiency, the surface portion of the lithium containing composite oxide and the impurity such as the lithium hydroxide react by the heat of the calcining, so that the Li is compensated from the impurity, the Li deficiency of the lithium containing composite oxide is reduced, and the impurity is decomposed. That is, as a result of the calcining, the lithium containing composite oxide powder in which the residual stress is removed and the impurity of the surface and the Li deficiency are reduced can be obtained.

The calcining temperature is desirably between 400° C. and 800° C., and furthermore, between 400° C. and 700° C. When the calcining temperature is higher than or equal to 400° C., the characteristics for the positive electrode active material of the lithium containing composite oxide powder can be expected to enhance. However, when the calcining temperature exceeds 700° C., agglomeration occurs, which is not desirable. It is desirable to hold the calcining temperature for 20 minutes or more, and furthermore, for 0.5 hours to 6 hours. The calcining is preferably carried out in the oxygen containing atmosphere. The calcining step is preferably carried out in the oxygen containing atmosphere, for example, in a gas atmosphere containing air medium, oxygen gas and/or ozone gas. In the case of the atmosphere containing oxygen gas, the oxygen gas concentration is between 20% by volume and 100% by volume, and furthermore between 50% by volume and 100% by volume.

### <Secondary Battery>

The lithium containing composite oxide powder according to the present invention can be used for the positive electrode active material of the secondary battery such as the non-aqueous electrolysis solution secondary battery, for example, the lithium ion secondary battery. Hereinafter, the non-aqueous electrolysis solution secondary battery using the positive electrode active material containing the lithium containing composite oxide powder will be described. The non-aqueous electrolysis solution secondary battery mainly includes a positive electrode, a negative electrode, and a non-aqueous electrolysis solution. Similar to the general non-aqueous electrolysis solution secondary battery, a separator is arranged between the positive electrode and the negative electrode.

The positive electrode includes a positive electrode active material that can insert and desorb lithium ions, and a binding material for binding the positive electrode active material. Furthermore, the conductive additive agent may be arranged. The positive electrode active material may include the lithium containing composite oxide powder alone, or may include the lithium containing composite oxide powder as well as one or more types of other positive electrode active materials used in the general non-aqueous electrolysis solution secondary battery within a range of not adversely affecting the effects obtained by the present invention.

The binding material and the conductive additive agent are not particularly limited, and merely need to be usable in the general non-aqueous electrolysis solution secondary battery. The conductive additive agent ensures the electrical conductivity of the electrode, and for example, one type or a mixture of two or more types of carbon substance powder body such as carbon black, acetylene black, graphite, and the like can be used for the conductive additive agent. The binding material plays a role of binding the positive electrode active material and the conductive additive agent, and for example, fluorine containing resin such as polyvinylidene fluoride, polytetrafluoroethylene, fluorine containing rubber, and the like, thermoplastic resin such as polypropylene, polyethylene, and the like can be used for the binding material.

The negative electrode to face the positive electrode can be formed by forming the metal lithium, which is the negative electrode active material, to a sheet form, or using the sheet-form metal lithium and pressure bonding the same to a current collector net of nickel, stainless steel, and the like. Lithium alloy or lithium compound can also be used in place of the metal lithium. Similar to the positive electrode, the negative electrode including the negative electrode active material, which can occlude and desorb lithium ions, and the binding material may be used. For example, organic compound calcined body such as natural graphite, artificial graphite, phenol resin, and the like, powder body of carbon substance such as coke and the like can be used for the negative electrode active material. Similar to the positive electrode, fluorine containing resin, thermoplastic resin, and the like can be used for the binding material.

The positive electrode and the negative electrode generally have the active material layer, which is obtained by binding at least the positive electrode active material or the negative electrode active material with the binding material, attached to the current collector. The positive electrode and the negative electrode are thus formed with the following method. An electrode mixture layer forming composition including the active material, the binding material, and the conductive additive agent, as necessary, is prepared, an appropriate solvent is added to the electrode mixture layer forming composition to obtain a paste form, such paste is applied onto the surface of the current collector, the current collector and the paste applied on the current collector are dried to form the electrode mixture layer on the current collector, and the electrode mixture layer is compressed to enhance the electrode density, as necessary, to form the positive electrode and the negative electrode.

The current collector may be a porous or nonporous conductive substrate made of metal material such as stainless steel, titanium, nickel, aluminum, copper, or the like, or a conductive resin. The porous conductive substrate includes, for example, fiber group molded body such as mesh body, net body, punching sheet, lath body, porous body, foam body, non-woven cloth, and the like. The nonporous conductive substrate includes, for example, foil, sheet, film, and the like. The current collector may use mesh made of metal or metal foil. The method for applying the electrode mixture layer forming composition to the current collector may be a conventionally known method such as doctor blade, bar coater, and the like.

N-methyl-2-pyrrolidene (NMP), methanol, methylisobutylketone (MIBK) and the like can be used for the solvent for viscosity preparation.

A general organic solvent electrolysis solution in which the electrolyte is dissolved in the organic solvent may be used for the non-aqueous electrolysis solution. The decomposition of the general electrolysis solution used in the non-aqueous electrolysis solution secondary battery is suppressed by using the lithium containing composite oxide powder according to the present invention for the positive electrode active material.

Generally, the organic solvent preferably includes the chain ester from the standpoint of load characteristic. Such chain ester includes, for example, chain carbonate represented by dimethyl carbonate, diethyl carbonate, ethylmethyl carbonate, organic solvent such as ethyl acetate, methylpropionate, and the like. Such chain ester may be used alone or by mixing two or more types, and in particular, the chain ester preferably occupies 50% by volume or more in the entire organic solvent, and in particular, the chain ester preferably occupies 65% by volume or more in the entire organic solvent to improve the low temperature characteristics.

In order to enhance the discharging capacity, however, it is preferable to use the organic solvent in which ester of high permittivity (permittivity: greater than or equal to 30) is mixed to the chain ester rather than that configured only with the chain ester. Specific examples of such ester include cyclic carbonate represented by ethylene carbonate, propylene carbonate, butylene carbonate, and vinylene carbonate, γ-butyrolactone, ethylene glycol sulfite, and the like, where ester of cyclic structure such as ethylene carbonate, propylene carbonate, and the like is particularly preferable. The ester of high permittivity is preferably contained by 10% by volume or more, and particularly, 20% by volume or more in the entire organic solvent from the standpoint of discharging capacity. The ester of high permittivity is more preferably contained by 40% by volume or less, and particularly 30% by volume or less in the entire organic solvent from the standpoint of load characteristic.

Among them, the electrolysis solution containing ethylene carbonate and ethylmethyl carbonate is widely used, where the use of the lithium containing composite oxide powder according to the present invention is also effective on such electrolysis solution.

For the electrolyte to be dissolved in the organic solvent, LiClO₄, LiPF₆, LiBF₄, LiAsF₆, LiSbF₆, LiCF₃SO₃, LiC₄F₉SO₃, LiCF₃CO₂, Li₂C₂F₄ (SO₃)₂, LiN(CF₃SO₂)₂, LiC(CF₃SO₂)₃, LiCₙF₂ₙ₊₁SO₃ (n≧₂) and the like are used alone or by mixing two or more types. Among them, LiPF₆, LiC₄F₉SO₃, and the like with which satisfactory charging/discharging characteristics for the electrolyte can be obtained are preferably used.

The concentration of the electrolyte in the electrolysis solution is not particularly limited, but the concentration of the electrolyte is preferably between 0.3 mol/dm³ and 1.7 mol/dm³, and in particular, between about 0.4 mol/dm³ and 1.5 mol/dm³.

Aromatic compound may be contained in the non-aqueous electrolysis solution to enhance the safety and the storage characteristic of the battery. For the aromatic compound, benzene including alkyl group such as cyclohexyl benzen, t-butylbenzene, and the like, biphenyl, fluorobenzene and the like are preferably used.

The separator preferably has sufficient strength and is able to hold great amount of electrolysis solution, and thus from such standpoint, microporous film, non-woven cloth, and the like made of polyolefin such as polypropylene, polyethylene, and copolymer of propylene and ethylene, and the like having a thickness of between 5 μm and 50 μm are preferably used. In particular, when the thin separator having a thickness of between 5 μm and 20 μm is used, the characteristic of the battery tends to easily degrade at the time of charging/discharging cycle, high temperature storage, and the like, and the safety also lowers. However, the battery can be stably functioned even by using such thin separator since the lithium ion secondary battery using the lithium containing composite oxide powder for the positive electrode active material excels in stability and safety.

The shape of the non-aqueous electrolysis solution secondary battery configured by the above configuring elements may take various shapes such as cylinder shape, stacked shape, coin shape, and the like. The separator can be sandwiched between the positive electrode and the negative electrode to form an electrode body with any shape. The positive electrode current collector and the negative electrode current collector are connected to the positive electrode terminal and the negative electrode terminal leading to the outside with a current collecting lead, and the like, the electrolysis solution is impregnated in the electrode body and the battery case is sealed to complete the non-aqueous electrolysis solution secondary battery.

In particular, with the non-aqueous electrolysis solution secondary battery in which the lithium containing composite oxide powder containing quadrivalent Mn of the lithium containing composite oxide powder according to the present invention is used for the positive electrode active material, the charging is first carried out to activate the positive electrode active material. However, in the non-aqueous electrolysis solution secondary battery described above, the lithium ions are released and the oxygen is generated at the time of initial charging. Thus, it is desirable to perform the initial charging before sealing the battery case.

In the non-aqueous electrolysis solution secondary battery in which the lithium containing composite oxide powder according to the present invention is used for the positive electrode active material, heat generation amount is reduced and excellent safety is obtained since the thermal stability of the lithium containing composite oxide powder is high. Generally, in the active material, it is known that the crystal structure is disrupted and the thermal stability lowers by the occlusion or release of the lithium ions involved in charging/discharging. In particular, the positive electrode active material containing oxygen easily generates oxygen with temperature rise by the heat generation. Thus, enhancing the thermal stability of the positive electrode active material and suppressing the generation of the oxygen gas lead to preventing ignition and thermal runaway of the battery. The lithium containing composite oxide powder according to the present invention has high thermal stability compared to that synthesized through a general solid phase method. This is because the lithium containing composite oxide powder according to the present invention is synthesized under the condition in which the generation of impurities is suppressed. Defining the thermal stability by numerical value, the lithium containing composite oxide powder in the charging state desirably indicates lower than or equal to 700 J/g when the heat generation amount is calculated from the heat generation peak (transition of heat flow of the differential scanning calorimetric curve) observed when heat analysis is carried out while raising the temperature in the differential scanning calorimetry measurement (DSC measurement). More desirably, it is greater than 0 J/g and lower than or equal to 675 J/g. In the heat generation peak, the maximum value of the heat flow is observed in a range of preferably between 250 and 350° C., 270 and 350° C., and more preferably between 280 and 350° C.

The lithium containing composite oxide powder in a state of being synthesized through the manufacturing process according to the present invention described above does not generate heat by simply raising the temperature. Thus, the heat generation amount adopts a value obtained by performing the DSC measurement on the lithium containing composite oxide powder in the charging state, in particular, the fully charged state. With the lithium containing composite oxide powder according to the present invention, low heat generation amount of lower than or equal to 700 J/g is indicated even in the fully charged state. The “fully charged state” in the present invention refers to a state in which the non-aqueous electrolysis solution secondary battery is charged by performing the CV charging for a predetermined time when the non-aqueous electrolysis solution secondary battery is constant current—constant voltage charged (CCCV charging) to a predetermined voltage. One example of the measurement of the heat generation amount will be described in detail later.

The non-aqueous electrolysis solution secondary battery using the lithium containing composite oxide powder obtained by the manufacturing process according to the present invention described above can be suitably used in the fields of automobiles, other than the fields of portable telephones, communication devices such as personal computer and the like, and information related devices. For example, the non-aqueous electrolysis solution secondary battery can be used for a power supply for the electric automobile by mounting the non-aqueous electrolysis solution secondary battery on the vehicle.

The embodiments of the manufacturing process for the lithium containing composite oxide powder according to the present invention, and furthermore, the non-aqueous electrolysis solution secondary battery have been described, but the present invention is not limited to the embodiments described above. The present invention can be implemented in various modes in which modifications, improvements, and the like contrived by those skilled in the art are made within a scope not deviating from the gist of the present invention.

### EXAMPLES

The present invention will be specifically described below using examples of a lithium containing composite oxide powder according to the present invention and a manufacturing process for the same.

### Example 1

### Synthesis of Li₂MnO₃

0.20 mol of lithium hydroxide monohydrate (LiOH.H₂O, 8.4 g) serving as the molten salt ingredient, and 0.020 mol of manganese dioxide (MnO₂, 1.74 g) serving as the metal compound ingredient were mixed to prepare the ingredient mixture. In this case, since the target product is Li₂MnO₃, (Li amount of target product)/(Li amount of molten salt ingredient) was 0.040 mol/0.2 mol=0.2 assuming all Mn of the manganese dioxide is supplied to Li₂MnO₃.

The ingredient mixture was placed in the crucible, and the crucible containing the ingredient mixture was placed in the vacuum drying container and vacuum dried for 12 hours at 120° C. Thereafter, the vacuum drying container was returned to atmospheric pressure, the crucible containing the ingredient mixture was taken out, and the crucible was immediately transferred to an electric furnace of 800° C. and heated for 12 hours in air medium of 800° C. In this case, the ingredient mixture in the crucible was molten to become the molten salt, and red product was precipitated in the crucible.

After the crucible was cooled until the crucible containing the molten salt became room temperature, the crucible was taken out from the electric furnace. Since 20 hours were required until the molten salt was solidified and cooled to room temperature (25° C.), the cooling speed was 39° C./hr. After the molten salt was sufficiently cooled and solidified, the entire crucible was immersed in 200 mL of ion exchange water and stirred to dissolve the solidified molten salt in the water. The product is insoluble in water, and thus the water was red suspension solution. By filtering the red suspension solution, transparent filtrate and red solid filtrate on the filter paper were obtained.

The obtained filtrate was further filtered while being sufficiently washed using acetone. The red solid after the washing was vacuum dried for about 12 hours at 120° C., and thereafter ground using a mortar and a pestle to obtain a red powder.

The average valency evaluation of Mn by the emission spectrochemical analysis (ICP) and the oxidation-reduction titration was carried out for the obtained red powder. As a result, the composition was recognized as Li₂MnO₃. The X-ray diffraction (XRD) measurement using the CuKα beam was conducted for the obtained red powder. According to the XRD, the obtained compound was found to have the lamellar rock salt structure.

The average valency evaluation of Mn was carried out in the following manner. 0.05 g of sample was placed in a conical flask, 40 mL of sodium oxalate solution having a concentration of 1% by mass was further accurately added to the conical flask, and 50 mL of H₂SO₄ was further added. The conical flask was then placed in a hot-water bath of 90° C. in the nitrogen gas atmosphere, and the sample was dissolved in the solution. 0.1 N of potassium permanganate solution was dropped in the solution in which the sample was dissolved up to the terminating point at which the solution dissolved with sample turned to a fine red color. The dropped amount of potassium permanganate solution in this case was assumed as titre V1. 20 mL of the sodium oxalate solution having a concentration of 1% by mass was accurately placed in another flask, and such conical flask was placed in the hot-water bath of 90° C. in the nitrogen gas atmosphere. The potassium permanganate solution of 0.1 N was dropped to the warmed sodium oxalate solution having the concentration of 1% by mass up to the terminating point at which the sodium oxalate solution turned to a fine red color. The dropped amount of potassium permanganate solution in this case was assumed as titre V2. From V1 and V2, the consumed amount of oxalate used until the Mn of high valency reduced to Mn²⁺ was calculated as an active oxygen amount according to the following equation.

active oxygen amount (%)={(2×V2−V1)×0.00080/sample amount}×100

In the equation described above, the unit of V1 and V2 is mL, and the unit of the sample amount is g. The average valency of the Mn was calculated from the Mn amount in the sample measured with the ICP and the active oxygen amount.

### Example 2

### Synthesis of Li₂MnO₃

Li₂MnO₃ was synthesized under exactly the same conditions as the Example 1 other than that 0.20 mol of anhydrous lithium hydroxide (LiOH, 4.79 g) was used for the molten salt ingredient in place of the lithium hydroxide monohydrate. As a result of performing the XRD measurement using the CuKα beam for the synthesized powder, the obtained compound was found to have the lamellar rock salt structure.

### Example 3

### Synthesis of LiCoO₂

0.20 mol of lithium hydroxide monohydrate (LiOH.H₂O, 8.4 g) serving as the molten salt ingredient, and 0.020 mol of cobalt hydroxide (Co(OH)₂, 1.86 g) serving as the metal compound ingredient were mixed to prepare the ingredient mixture. In this case, the target product is LiCoO₂, and thus assuming Co of the cobalt hydroxide are all supplied to the LiCoO₂, (Li amount of target product)/(Li amount of molten salt ingredient) was 0.020 mol/0.2 mol=0.1.

The ingredient mixture was placed in the crucible, and the crucible containing the ingredient mixture was placed in the vacuum drying container and vacuum dried for 12 hours at 120° C. Thereafter, the vacuum drying container was returned to atmospheric pressure, the crucible containing the ingredient mixture was taken out, and the crucible was immediately transferred to an electric furnace of 800° C. and heated for 12 hours in air medium of 800° C. In this case, the ingredient mixture in the crucible was molten to become the molten salt, and black product was precipitated in the crucible.

After the crucible was cooled until the crucible containing the molten salt became room temperature, the crucible was taken out from the electric furnace. Since 15 hours were required until the molten salt was solidified and cooled to room temperature (25° C.), the cooling speed was 52° C./hr. After the molten salt was sufficiently cooled and solidified, the entire crucible was immersed in 200 mL of ion exchange water and stirred to dissolve the solidified molten salt in the water. The product is insoluble in water, and thus the water was black suspension solution. By filtering the black suspension solution, transparent filtrate and black solid filtrate on the filter paper were obtained.

The obtained filtrate was further filtered while being sufficiently washed using acetone. The black solid after the washing was vacuum dried for about 12 hours at 120° C., and thereafter ground using a mortar and a pestle to obtain a black powder.

The XRD measurement using the CuKα beam was conducted for the obtained black powder. According to the XRD, the obtained compound was found to be LiCoO₂ having the lamellar rock salt structure.

### Example 4

### Synthesis of LiNiO₂

0.30 mol of lithium hydroxide monohydrate (LiOH.H₂O, 12.6 g) serving as the molten salt ingredient, and 0.030 mol of nickel hydroxide (Ni(OH)₂, 2.78 g) serving as the metal compound ingredient were mixed to prepare the ingredient mixture. In this case, the target product is LiNiO₂, and thus assuming Ni of the nickel hydroxide are all supplied to the LiNiO₂, (Li amount of target product)/(Li amount of molten salt ingredient) was 0.030 mol/0.3 mol=0.1.

The ingredient mixture was placed in the crucible, and the crucible containing the ingredient mixture was placed in the vacuum drying container and vacuum dried for 12 hours at 120° C. Thereafter, the vacuum drying container was returned to atmospheric pressure, the crucible containing the ingredient mixture was taken out, and the crucible was immediately transferred to an electric furnace of 800° C. and heated for 12 hours in air medium of 800° C. In this case, the ingredient mixture in the crucible was molten to become the molten salt, and black product was precipitated in the crucible.

After the crucible was cooled until the crucible containing the molten salt became room temperature, the crucible was taken out from the electric furnace. Since 24 hours were required until the molten salt was solidified and cooled to room temperature (25° C.), the cooling speed was 32° C./hr. After the molten salt was sufficiently cooled and solidified, the entire crucible was immersed in 200 mL of ion exchange water and stirred to dissolve the solidified molten salt in the water. The product is insoluble in water, and thus the water was black suspension solution. By filtering the black suspension solution, transparent filtrate and black solid filtrate on the filter paper were obtained.

The obtained filtrate was further filtered while being sufficiently washed using acetone. The black solid after the washing was vacuum dried for about 12 hours at 120° C., and thereafter ground using a mortar and a pestle to obtain a black powder.

The XRD measurement using the CuKα beam was conducted for the obtained black powder. According to the XRD, the obtained compound was found to be LiNiO₂ having the lamellar rock salt structure.

### Example 5

### Synthesis of LiCo_{1/3}Ni_{1/3}Mn_{1/3}O₂

0.30 mol of lithium hydroxide (LiOH.H₂O, 12.6 g) serving as the molten salt ingredient, and the precursor (1.0 g) serving as the metal compound ingredient were mixed to prepare the ingredient mixture. The synthesizing procedure of the precursor will be described below.

0.16 mol of Mn(NO₃)₂.6H₂O (45.9 g), 0.16 mol of Co(NO₃)₂.6H₂O (46.6 g), and 0.16 mol of Ni(NO₃)₂.6H₂O (46.5 g) were dissolved in 500 mL of distilled water to produce the metal salt containing aqueous solution. 50 g (1.2 mol) of LiOH.H₂O dissolved in the 300 mL of distilled water was dropped over two hours while stirring the aqueous solution in the ice bath using a stirrer so that the aqueous solution becomes alkaline, and the precipitation of the metal oxide was precipitated. The precipitation solution was matured for one day under the oxygen atmosphere while being held at 5° C. The obtained precipitation was filtered and washed using the distilled water to obtain the precursor of Mn:Co:Ni=0.16:0.16:0.16.

The obtained precursor was found to have a mixed phase of Mn₃O₄, Co₃O₄, and NiO by the XRD measurement. Thus, the transition metal element content of 1 g of precursor is 0.013 mol. In this case, assuming all the transition metals of the precursor are supplied to the target product, (Li of target product)/(Li of molten salt ingredient) was 0.013 mol/0.3 mol=0.043.

The ingredient mixture was placed in the crucible, and the crucible containing the ingredient mixture was placed in the vacuum drying container and vacuum dried for 12 hours at 120° C. Thereafter, the vacuum drying container was returned to atmospheric pressure, the crucible containing the ingredient mixture was taken out, and the crucible was immediately transferred to an electric furnace of 800° C. and heated for 6 hours in air medium of 800° C. In this case, the ingredient mixture in the crucible was molten to become the molten salt, and black product was precipitated in the crucible.

After the crucible was cooled until the crucible containing the molten salt became room temperature, the crucible was taken out from the electric furnace. Since 15 hours were required until the molten salt was solidified and cooled to room temperature (25° C.), the cooling speed was 52° C./hr. After the molten salt was sufficiently cooled and solidified, the entire crucible was immersed in 200 mL of ion exchange water and stirred to dissolve the solidified molten salt in the water. The product is insoluble in water, and thus the water was black suspension solution. By filtering the black suspension solution, transparent filtrate and black solid filtrate on the filter paper were obtained.

The obtained filtrate was further filtered while being sufficiently washed using acetone. The black solid after the washing was vacuum dried for about 6 hours at 120° C., and thereafter ground using a mortar and a pestle to obtain a black powder.

The average valency evaluation of Mn by the emission spectrochemical analysis (ICP) and the oxidation-reduction titration was carried out for the obtained black powder. As a result, the composition was recognized as LiCo_{1/3}Ni_{1/3}Mn_{1/3}O₂. The X-ray diffraction (XRD) measurement using the CuKα beam was conducted for the obtained black powder. According to the XRD, the obtained compound was found to have the lamellar rock salt structure.

### Comparative Example 1

### Synthesis of LiCo_{1/3}Ni_{1/3}Mn_{1/3}O₂

LiCo_{1/3}Ni_{1/3}Mn_{1/3}O₂ was synthesized under completely the same condition as the Example 5 other than being heated for six hours in air medium of 600° C. in the electric furnace of 600° C. The cooling speed was 115° C./hr, since five hours were required from 600° C. to 25° C.

The average valency evaluation of Mn by the emission spectrochemical analysis (ICP) and the oxidation-reduction titration was carried out for the synthesized powder. As a result, the composition was recognized as LiCo_{1/3}Ni_{1/3}Mn_{1/3}O₂. The XRD measurement using the CuKα beam was conducted for the synthesized powder. According to the XRD, the obtained compound was found to have the lamellar rock salt structure. The obtained powder was found to be fine powder since the half bandwidth is wide.

### <Observation of Particles>

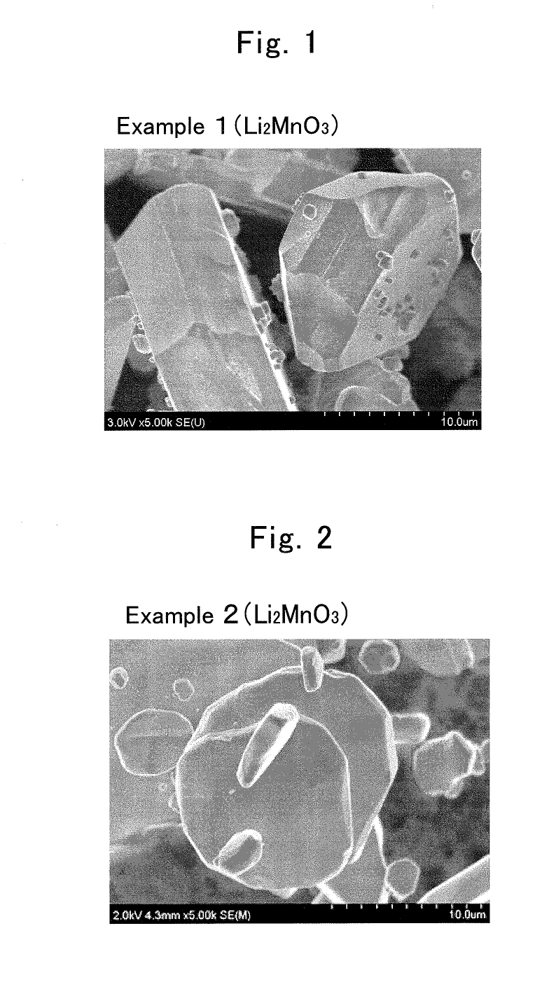

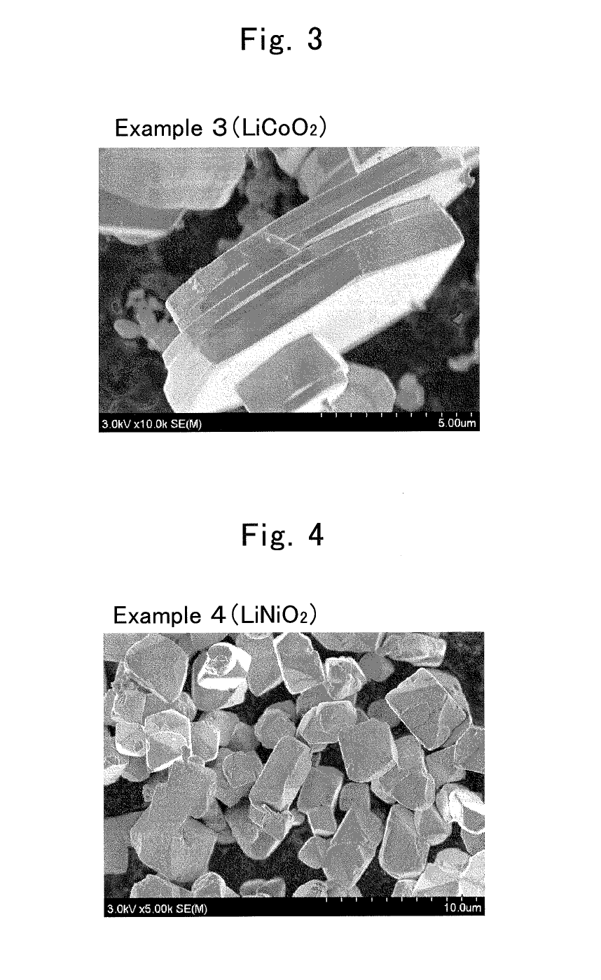

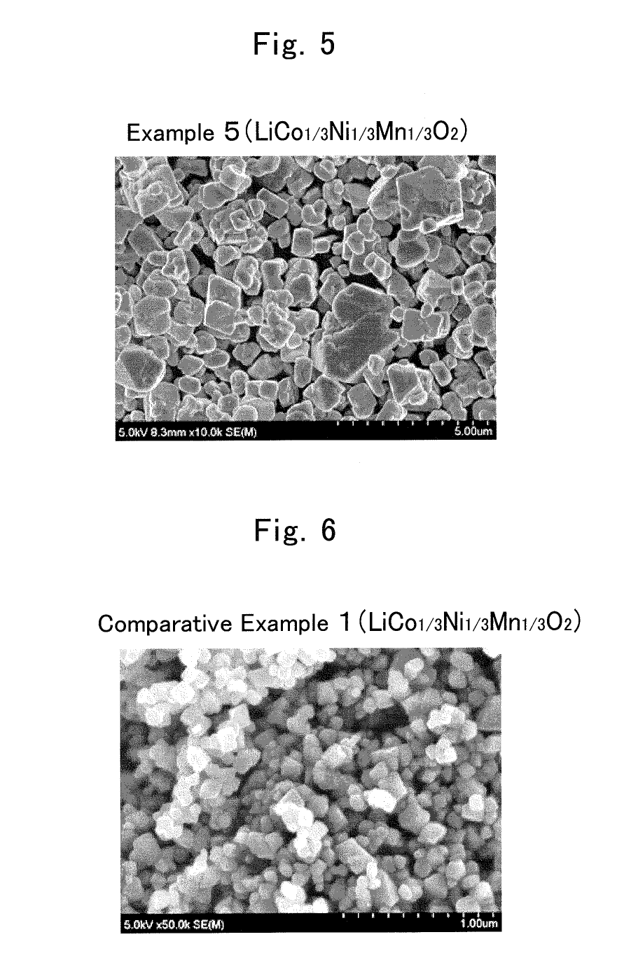

The lithium containing composite oxide powder of each example and comparative example synthesized according to the above procedure was observed using the scanning electron microscope (SEM). The observation result of each lithium containing composite oxide powder is shown in FIG. 1 to FIG. 6.

The maximum diameter of a plurality of particles was measured from the image of the plurality of particles obtained by the SEM observation, and the average primary particle diameter was calculated from the average value of the plurality of maximum diameters. The result is as shown below. Extremely small particles attached to the particle surface as shown in FIG. 1 are non-grown by-product, but the average primary particle diameter was calculated including the particles on the surface as one particle.

Example 1 (Li₂MnO₃ powder): 16 μm

Example 2 (Li₂MnO₃ powder): 14 μm

Example 3 (LiCoO₂ powder): 9 μm

Example 4 (LiNiO₂ powder): 5 μm

Example 5 (LiCo_{1/3}Ni_{1/3}Mn_{1/3}O₂ powder): 2 μm

Comparative Example 1 (LiCo_{1/3}Ni_{1/3}Mn_{1/3}O₂ fine powder): 100 nm

### <Measurement of Specific Surface Area>

The specific surface area of the lithium containing composite oxide powder of each example and comparative example was measured using the BET method by low temperature low humidity physical adsorption. The adsorbate in the BET method was nitrogen. The result is as shown below.

Example 1 (Li₂MnO₃ powder): 0.74 m²/g

Example 2 (Li₂MnO₃ powder): 0.96 m²/g

Example 3 (LiCoO₂ powder): 1.72 m²/g

Example 4 (LiNiO₂ powder): 2.03 m²/g

Example 5 (LiCo_{1/3}Ni_{1/3}Mn_{1/3}O₂ powder): 5.58 m²/g

Comparative Example 1 (LiCo_{1/3}Ni_{1/3}Mn_{1/3}O₂ fine powder): 20.6 m²/g

### <Electron Beam Diffraction>

The lithium containing composite oxide powder of each example was observed with the transmission electron microscope (TEM), a limited view electron beam diffraction under the condition of acceleration voltage 200 kV was performed, and identification and evaluation of the single crystal were conducted. The limited view electron beam diffraction pattern in which one particle is entirely in the limited view was observed with regular diffraction points indicating the characteristics of the single crystal regardless of which particle was observed. The diffraction pattern obtained from different positions in the same plane in one particle was observed as diffraction points indicating the same plane indices with respect to each other. Therefore, the obtained particle was found to be a single crystal particle without crystal grain boundary.

### <Charging/Discharging Test>

Four types of lithium ion secondary batteries #03 to #05 and #C1 were produced using the lithium containing composite oxide powder of the third to Example 5s and the Comparative Example 1 synthesized through the above procedure respectively as positive electrode active materials.

One of the lithium containing composite oxide, the acetylene black serving as the conductive additive agent, and the polytetrafluoroethylene (PTFE) serving as the binding material was mixed at a percentage of 50:40:10 in mass ratio to form the mixture. The mixture was then pressure attached to the aluminum mesh, which is the current collector. Thereafter, the current collector and the mixture pressure attached to the current collector were vacuum dried for 12 hours or more at 120° C., and then cut to a size of φ12 mm after vacuum drying, the resultant of which was assumed as the positive electrode. The negative electrode to face the positive electrode was graphite of φ14 mm and thickness of 30 μm.

The fine porous polyethylene film having a thickness of 20 μm was sandwiched as a separator between the positive electrode and the negative electrode to obtain the electrode body battery. Such electrode body battery was accommodated in the battery case (CR2032 coil cell manufactured by Hohsen Co.). To the battery case was injected the non-aqueous electrolysis solution in which LiPF₆ was dissolved at the concentration of 1.0 mo/L to the mixed solvent in which the ethylene carbonate and the ethylmethyl carbonate were mixed at a volume ratio 1:2 to obtain the lithium ion secondary battery.

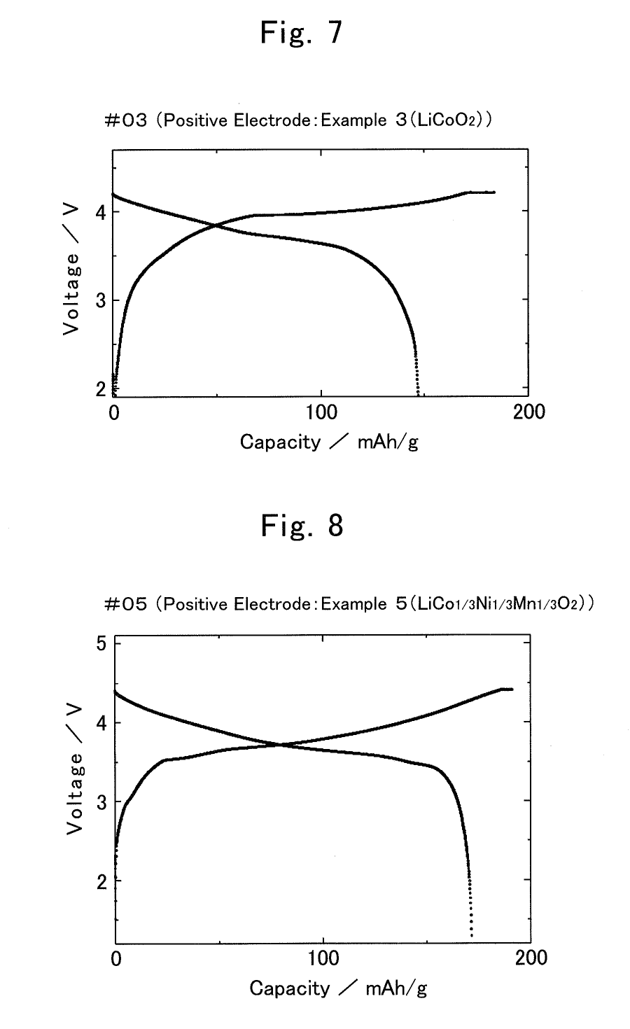

The charging/discharging test was conducted at room temperature (25° C.) using the produced lithium ion secondary battery. In the charging, the constant current charging was performed up to a predetermined voltage (4.2 V for #03) described in table 1 at a rate of 0.2 C, and thereafter, the charging was performed at a constant voltage up to the current value of 0.02 C. The discharging was performed at a rate of 0.2 C up to a predetermined voltage (2.0 V for #03) described in table 1. The charging/discharging curve of the first time (first cycle) of the lithium ion secondary battery #03 and the lithium ion secondary battery #05 is shown in FIG. 7 and FIG. 8. The capacity maintaining rate (discharging capacity of 50th cycle/discharging capacity of the 1st cycle) was obtained from the discharging capacity of the initial time and the 50th cycle. The result is shown in table 1.

TABLE 1

| | | | DISCHARGING | CAPACITY |
|---|---|---|---|---|
| | | | CAPACITY | MAINTAINING |
| | POSITIVE | | OF INITIAL | RATE |
| SECONDARY | ELECTRODE ACTIVE | VOLTAGE | TIME | AFTER 50 |
| BATTERY | MATERIAL | RANGE | (mAh/g) | CYCLES (%) |
| #03 | EXAMPLE 3 | 4.2 V to 2.0 V | 148 | 98 |
| | (LiCoO₂) | | | |
| #04 | EXAMPLE 4 | 4.2 V to 2.0 V | 150 | 95 |
| | (LiNiO₂) | | | |
| #05 | EXAMPLE 5 | 4.4 V to 1.4 V | 170 | 98 |
| | (LiCo_{1/3}Ni_{1/3}Mn_{1/3}O₂) | | | |
| #C1 | COMPARATIVE | 4.4 V to 1.4 V | 160 | 73 |
| | EXAMPLE 1 | | | |
| | (LiCo_{1/3}Ni_{1/3}Mn_{1/3}O₂) | | | |

The lithium ion secondary batteries of #03 to #05 had very high capacity maintaining rate after 50 cycles. Such lithium ion secondary batteries are assumed to have enhanced cyclability as a result of suppressing the disruption of particles and decomposition of electrolysis solution in charging/discharging by using the powder containing the single crystal particles of lithium containing composite oxide for the positive electrode active material. In particular, the lithium ion secondary battery of #05 had a cutoff voltage of charging of 4.4 V, which is higher than the lithium ion secondary batteries of #03 and #04, and thus it is assumed that degradation of the electrolysis solution easily occurs. However, the lithium ion secondary battery of #05 had a capacity maintaining rate of 98% after 50 cycles, and excelled in cyclability. It was found that the initial discharging capacity is large and the average voltage is high in any lithium ion secondary batteries as shown in FIG. 7 and FIG. 8.

Furthermore, comparing the lithium ion secondary batteries of #05 and #C1 in which the powder containing the single crystal particle including the lithium containing composite oxide having the same composition with respect to each other was used for the positive electrode active material, the initial discharging capacity and the capacity maintaining rate of the lithium ion secondary battery of #05 excelled over the lithium ion secondary battery of #C1. The different between such batteries lies in the average primary particle diameter of the lithium containing composite oxide used for the positive electrode active material. Comparing the capacity maintaining rate of the lithium ion secondary batteries of #05 and #C1, it was found that the cyclability greatly lowered when the lithium manganese oxide powder used for the positive electrode active material is a fine powder of nano order. Furthermore, according to the results of XRD, it was assumed that the lithium containing composite oxide of the Example 5 has higher crystallinity than the Comparative Example 1. The difference in the crystallinity of the two is assumed to have great influence on the battery characteristic.

That is, it was found that the non-aqueous electrolysis solution secondary battery excelling in cyclability is obtained by using the lithium containing composite oxide powder according to the present invention.

### <Differential Scanning Calorimetry Measurement (DSC Measurement)>

In order to examine the thermal stability of the lithium containing composite oxide powder according to the present invention, the DSC measurement was conducted through the following procedure for the lithium containing composite oxide powder (i.e., Lico_{1/3}Ni_{1/3}Mn_{1/3}O₂ powder) of the Example 5 and the conventional art synthesized through the above procedure. For the conventional lithium containing composite oxide powder, LiCo_{1/3}Ni_{1/3}Mn_{1/3}O₂ powder (primary particle diameter observed by the SEM was between 200 and 500 μm) commercially available as the battery material and synthesized by the solid phase method was used.

The LiCo_{1/3}Ni_{1/3}Mn_{1/3}O₂ becomes a crystal structure having low thermal stability since Li is released. Thus, the lithium ion secondary battery including the positive electrode containing LiCo_{1/3}Ni_{1/3}Mn_{1/3}O₂ was prepared, and the DSC measurement was conducted for the LiCo_{1/3}Ni_{1/3}Mn_{1/3}O₂ after being in the charged state.

The lithium containing composite oxide of the Example 5 or the conventional art, the acetylene black serving as the conductive additive agent, the polyvinylidene fluoride serving as the binding material were mixed at a percentage of 88:6:6 in mass ratio for the positive electrode active material to obtain a mixture of slurry form. The mixture was then applied to one side of the aluminum foil, which is the current collector, and then pressed and molded, and heated for six hours at 120° C. The positive electrode having the positive electrode active material layer on the surface of the current collector was thereby obtained. The graphite negative electrode having sufficient capacity to occlude the lithium moving from the positive electrode to the negative electrode was used for the negative electrode facing the positive electrode.

The lithium ion secondary battery was produced using the electrode produced through the above procedures. The polypropylene porous film serving as the separator was sandwiched between the positive electrode and the negative electrode in which the positive electrode active material layer containing the lithium containing composite oxide powder and the negative electrode active material layer containing the graphite are opposed to each other to produce the electrode body. The electrode body was sealed along with the electrolysis solution by the aluminum film to obtain a laminate cell. Upon sealing, two aluminum films were thermally welded except at one part of the periphery to form a bag shape, and the electrode body and the electrolysis solution were inserted from the opening and the opening was air tightly sealed while vacuuming. In this case, the distal end of the current collector on the positive electrode side and the negative electrode side is projected out from the end edge of the film to be able to connect with the external terminal.

The non-aqueous electrolysis solution in which LiPF₆ is dissolved at a concentration of 1.0 mol/L (1.0 M) in the mixed solvent in which ethylene carbonate, ethylmethyl carbonate, and dimethyl carbonate are mixed at a volume ratio of 3:3:4 was used for the electrolysis solution.

The two types of lithium ion secondary batteries that were produced are respectively charged through the following procedure at room temperature (25° C.) to be in a fully-charged state, thus obtaining the lithium containing composite oxide having LiCo_{1/3}Ni_{1/3}Mn_{1/3}O₂ as a basic composition and in which Li is deficient.

The constant current-constant voltage charging was performed to 4.2 V at the rate of 0.2 C until the fully-charged state is obtained. The constant voltage charging was performed for 2.5 hours after the termination of constant current charging, and then the charging was completed. The lithium ion secondary battery was decomposed, and the positive electrode was taken out. The positive electrode that was taken out was washed using dimethyl carbonate. After drying the washed positive electrode, the positive electrode active material layer containing the lithium containing composite oxide powder of after lithium was released was stripped from the positive electrode current collector in the argon atmosphere. 5 mg of the stripped positive electrode active material layer was weighed and accommodated in the SUS pressure resistance cell (manufactured by Shimadzu Co.). Furthermore, 2.8 L of the solution in which LiPF₆ was dissolved at a concentration of 1.0 mol/L in the mixed solvent in which ethylene carbonate, ethylmethyl carbonate, and dimethyl carbonate were mixed at a volume ratio of 3:3:4 was added, and the SUS pressure resistance cell was sealed. The sample prepared in this manner contained the positive electrode active material, the conductive additive agent, the binding material, and the electrolysis solution, and hence contained components same as the positive electrode of the lithium ion secondary battery performed with charging.

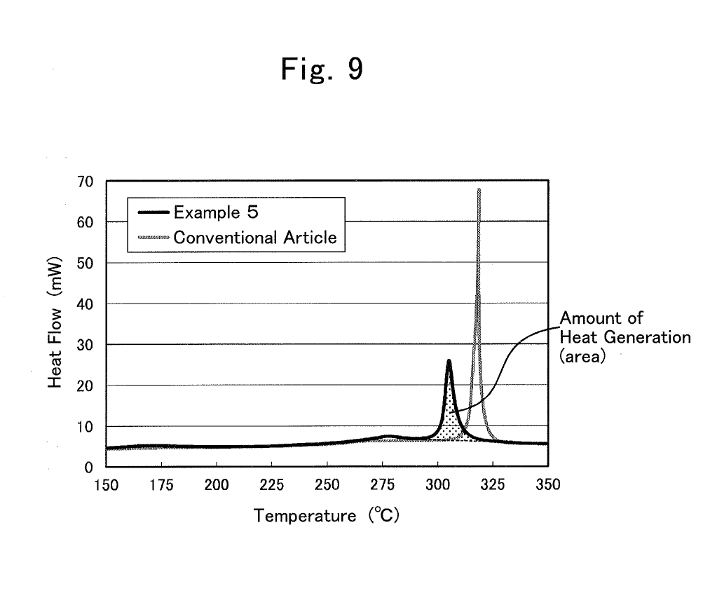

The differential scanning calorimetric curve of the sample prepared through the above procedure, and accommodated in the SUS pressure resistance cell was measured using the high sensitivity differential scanning calorimeter Thermo Plus EVO/DSC8230 (manufactured by Rigaku Co.). The DSC measurement was conducted with the sample temperature raised from the room temperature to 450° C. at the temperature raising speed of 5° C./min in the nitrogen gas atmosphere. The differential scanning calorimetric curve in the range of between 150 and 350° C. is shown in FIG. 9. A significant heat generation peak is not found at lower than or equal to 150° C. and at higher than or equal to 350° C. not shown.

Using the software accompanying the calorimeter described above, a heat generation amount (unit: J) was calculated from an area (area of the heat generation peak) of the portion surrounded by the differential scanning calorimetric curve and the dotted line shown in FIG. 9 corresponding to the transition of heat amount of the differential scanning calorimetric curve, and converted to the heat generation amount (unit: J/g) per unit mass of the lithium containing composite oxide powder. The dotted line shown in FIG. 9 is a background simply added with respect to the differential scanning calorimetric curve to explain the area corresponding to the heat generation amount. The background and the heat generation amount are actually introduced by the software accompanying the calorimeter and calculated. Since the detected heat generation peak is the peak originating from the heat generation of the lithium containing composite oxide, the heat generation amount (unit: J/g) of the lithium containing composite oxide per unit mass was calculated from the mass of the lithium containing composite oxide contained in the sample. The result is shown below.

LiCo_{1/3}Ni_{1/3}Mn_{1/3}O₂ powder of Example 5: 650 J/g

Conventional LiCo_{1/3}Ni_{1/3}Mn_{1/3}O₂ powder: 750 J/g

The maximum value of the heat generation peak originating from the lithium containing composite oxide was observed around 300° C. and 320° C. The heat generation amount of the LiCo_{1/3}Ni_{1/3}Mn_{1/3}O₂ powder of the Example 5, which is the lithium containing composite oxide powder synthesized by the molten salt method was low 650 J/g. That is, the lithium containing composite oxide powder according to the present invention has high thermal stability, and the non-aqueous electrolysis solution secondary battery using such powder as the positive electrode active material excels in safety. For reference, the charging was performed under the same conditions as described above and thereafter, the DSC same as above was performed for the LiCo_{1/3}Ni_{1/3}Mn_{1/3}O₂ powder synthesized though the procedure similar to the Example 5 other than that the reaction temperature was 900° C. The heat generation amount exceeded 700 J/g, which is a heat generation amount closer to the conventional article.

1-21. (canceled)

22. A lithium containing composite oxide powder comprising a single crystal particle containing a lithium containing composite oxide that is manufactured by a molten salt method and that includes at least lithium and another one or more metal elements and in which a crystal structure belongs to a lamellar rock salt structure, wherein;
an average primary particle diameter is greater than or equal to 200 nm and smaller than or equal to 30 μm; and
the lithium containing composite oxide includes a lithium element, and one or more types of metal element in which a quadrivalent manganese is essential.

23. The lithium containing composite oxide powder according to claim 22, wherein a specific surface area is greater than or equal to 0.5 m²/g and smaller than or equal to 20 m²/g.

24. The lithium containing composite oxide powder according to claim 22, wherein the single crystal particle includes a single crystal manufactured in a molten salt of lithium hydroxide.

25. The lithium containing composite oxide powder according to claim 22, wherein the average primary particle diameter is greater than or equal to 300 nm and smaller than or equal to 30 μm.

26. The lithium containing composite oxide powder according to claim 22, wherein the single crystal particle includes a single particle.

27. The lithium containing composite oxide powder according to claim 22, wherein the lithium containing composite oxide further contains one or more types of metal element in which at least one type of a triad cobalt, a triad nickel, and a triad iron is essential.

28. The lithium containing composite oxide powder according to claim 22, wherein the lithium containing composite oxide has a basic composition of xLi₂M¹O₃.(1-x)LiM²O₂ (where 0≦x≦1, M¹ is one or more types of metal element in which quadrivalent Mn is essential, M² is one or more types of metal element in which at least one type of triad Co, triad Ni, and triad Fe is essential or two or more types of metal element in which a quadrivalent Mn is essential, a part of Li may be substitutable with H).

29. A positive electrode active material for a non-aqueous electrolysis solution secondary battery comprising the lithium containing composite oxide powder according to claim 22.

30. The positive electrode active material for the non-aqueous electrolysis solution secondary battery according to claim 29, wherein the lithium containing composite oxide powder in a charged state indicates smaller than or equal to 700 J/g when a heat generation amount is calculated from a heat generation peak observed between 250 and 350° C. upon performing thermal analysis while raising the temperature in a differential scanning calorimetry measurement (DSC measurement).

31. The positive electrode active material for the non-aqueous electrolysis solution secondary battery according to claim 30, wherein the lithium containing composite oxide powder has a basic composition of LiCo_{1/3}Ni_{1/3}Mn_{1/3}O₂.

32. A non-aqueous electrolysis solution secondary battery comprising a positive electrode containing the positive electrode active material according to claim 29, a negative electrode, and a non-aqueous electrolysis solution.

33. A vehicle mounted with the non-aqueous electrolysis solution secondary battery according to claim 32.

34. A manufacturing process for the lithium containing composite oxide powder according to claim 22, the process comprising the steps of:
single crystal growing step of reacting a metal containing ingredient, which includes a metal element, in a molten salt of a lithium hydroxide containing lithium of a mol ratio exceeding a theoretical composition of lithium contained in the lithium containing composite oxide at a reaction temperature of higher than or equal to 650° C. and lower than or equal to 900° C.;
cooling step of cooling the molten salt of after the single crystal growing step; and
collecting step of collecting the generated lithium containing composite oxide from a cooled solid body.

35. The manufacturing process for the lithium containing composite oxide powder according to claim 34, wherein the cooling step cools the molten salt of after the single crystal growing step at a slow speed of lower than or equal to 100° C./hr.

36. The manufacturing process for the lithium containing composite oxide powder according to claim 34, wherein the reaction temperature is higher than or equal to 700° C. and lower than or equal to 900° C.

37. The manufacturing process for the lithium containing composite oxide powder according to claim 34, wherein the molten salt is formed by dissolving a molten salt ingredient containing anhydrous lithium hydroxide.

38. The manufacturing process for the lithium containing composite oxide powder according to claim 34, further comprising the steps of preparing an ingredient mixture of the molten salt ingredient containing lithium hydroxide monohydrate and the metal containing ingredient, and drying the ingredient mixture, before the single crystal growing step.

39. The manufacturing process for the lithium containing composite oxide powder according to claim 34, wherein the metal containing ingredient includes one or more types of manganese, iron, cobalt, and nickel.

40. The manufacturing process for the lithium containing composite oxide powder according to claim 34, wherein the collecting step includes a separation and collecting step of dissolving the molten salt solidified by the cooling step in a polar protic solvent, and separating the lithium containing composite oxide generated in the single crystal growing step from the solidified molten salt.

41. The manufacturing process for the lithium containing composite oxide power according to any one of claim 34, further comprising The calcining step of calcining the lithium containing composite oxide powder collected in the collecting step.
